(19) United States
(12) Patent Application Publication
(10) Pub. No.: US 2008/0203507 A1
(43) Pub. Date: Aug. 28, 2008

(54) Image sensors for zoom lenses and fabricating methods thereof

(75) Inventors: Kyoung-sik Moon, Hwaseong-si (KR); Jong-jin Lee, Seoul (KR); Bum-suk Kim, Seoul (KR); Yun-ho Jang, Seoul (KR); Jung-chak Ahn, Yongin-si (KR)

Correspondence Address: HARNESS, DICKEY & PIERCE, P.L.C., P.O. BOX 8910, RESTON, VA, 20195, US

(73) Assignee: SAMSUNG ELECTRONICS CO., LTD

(21) Appl. No.: 11/892,462

(22) Filed: Aug. 23, 2007

(30) Foreign Application Priority Data
Feb. 27, 2007 (KR) 10-2007-0019918

(51) Int. Cl. H01L 31/0224; H01L 21/00; H01L 31/0232

(52) U.S. Cl. 257/432; 438/69; 438/70; 438/98; 257/E31.127; 257/E21.002

(57) ABSTRACT

An image sensor includes a semiconductor substrate on which a plurality of photo diodes are formed. A plurality of interlayer dielectrics are formed above the semiconductor substrate, and a plurality of metal lines are formed on each of the interlayer dielectrics. A plurality of micro lenses are formed above the uppermost one of the interlayer dielectrics. The light passing through the zoom lenses is incident on the respective micro lenses. The plurality metal lines formed on at least one of the plurality of interlayer dielectrics have the same width.

### PRIORITY STATEMENT

This non-provisional U.S. patent application claims priority under 35 U.S.C. §119 to Korean Patent Application No. 10-2007-0019918, filed on Feb. 27, 2007, in the Korean Intellectual Property Office, the entire contents of which is incorporated herein by reference.

### BACKGROUND

### Description of the Conventional Art

A conventional image sensor is a semiconductor device, which converts an optical image into an electric signal. A complementary metal oxide semiconductor (CMOS) image sensor and a charge coupled device (CCD) are examples of conventional image sensors. Conventional CMOS image sensors and the CCDs use lenses to capture images. In conventional image sensors, light having different incident angles is incident on respective regions of the image sensor by the lens.

FIG. 1 is a schematic sectional view of a conventional image sensor. Referring to FIG. 1, a conventional image sensor 100 may include a semiconductor substrate 110 in which a plurality of photo diodes PD_0, PD_1, PD_2, PD_3, and PD_4 may be formed. A plurality of interlayer dielectrics 220, a plurality of color filters CF_0, CF_1, CF_2, CF_3, and CF_4 and a plurality of micro lenses ML_0, ML_1, ML_2, ML_3, and ML_4 may be formed on the substrate 110

The interlayer dielectrics 220 may be successively formed on the semiconductor substrate 110 including photo diodes PD_0, PD_1, PD_2, PD_3, and PD_4. A plurality of lines MT may be formed on each of the interlayer dielectrics 220. The lines MT may be arranged to not interfere with the photo diodes PD_0, PD_1, PD_2, PD_3 and PD_4. When the lines MT are formed of metal, the lines MT may function as a light break layer. The color filters CF_0, CF_1, CF_2, CF_3 and CF_4 may be formed above the interlayer dielectrics 220. Micro lenses ML_0 ML_1, ML_2, ML_3 and ML_4 may be formed above the color filters CF_0, CF_1, CF_2, CF_3 and CF_4. Over-coating layers 240, functioning as planar layers, may be formed between the interlayer dielectric 220 and the color filters CF_0, CF_1, CF_2, CF_3 and CF_4, and between the color filters CF_0, CF_1, CF_2, CF_3 and CF_4 and the micro lenses ML_0, ML_1, ML_2, ML_3 and ML_4. Although not shown in FIG. 1, a lens for transferring externally incident light to the micro lenses ML_0, ML_1, ML_2, ML_3 and ML_4 may be disposed above the micro lenses ML_0, ML_1, ML_2, ML_3 and ML_4.

Arrows in FIG. 1 indicate paths of light passing through the lens. For example, the light passing through the lens may be directed to the photo diode PD_2 through the micro lens ML_2 and the color filter CF_2. When the lens is not a zoom lens, but a normal lens, the light path may be uniform. However, when using a zoom lens, the light path may vary according to the zoom lens. Thus, the light passing through the micro lens ML_2 may not be incident on the target photo diode PD_2, but may be incident on peripheral photo diodes PD_1 and PD_3.

FIG. 2 illustrates light incident on a photo diode in accordance with magnification of a conventional zoom lens.

Referring to FIG. 2, the light 210_1, 210_2, 210_3 and 210_4 incident through the relatively low magnification lens may be fully directed to the corresponding target photo diodes PD_1, PD_2, PD_3 and PD_4. On the other hand, the lights 230_1, 230_2, 230_3 and 230_4 incident through the relatively high magnification lens may not be fully directed to the corresponding target photo diodes PD_1, PD_2, PD_3 and PD_4. For example, a portion 250_1 of light 230_1 may be blocked by the metal line 130_2 and a portion 250_2 of light 240_2 may be blocked by metal line 130_4. These portions 250_1 and 250_2 may not be directed to the corresponding target photo diodes PD_1 and PD_3. This may be caused by, as shown in FIG. 1, metal lines MT having identical widths in a floating diffusion (FD) shared architecture. For example, the metal lines 130_1 and 130_3 each having a relatively narrow width may be alternately arranged with the metal lines 130_2 and 130_4 having a relatively wide width. Therefore, an amount of each of the light incident on the respective photo diodes PD_1 and PD_3 may be different from an amount of light incident on the respective photo diodes PD_2 and PD_4. This may cause sensitivity difference between Gr and Gb. For example, a sensitivity difference may occur between adjacent green (Gr) pixels and red (Red) pixels, and/or adjacent green (Gr) pixels adjacent to blue (Blue) pixels. In addition, a color tint (e.g., a color of the image) may not become unnatural and be divided into block units. Thus, the image may be displayed by block units.

### SUMMARY

Example embodiments relate to image sensors. For example, example embodiments relate to image sensors and methods of fabricating image sensors.

Example embodiments provide image sensors configured to suppress and/or prevent a sensitivity difference between Gr and Gb and a color tint phenomenon by providing additional metal lines in addition to existing metal lines even when using a zoom lens.

Example embodiments provide methods of fabricating image sensors.

According to at least one example embodiment, an image sensor for detecting lights passing through the zoom lens may include: a semiconductor substrate on which a plurality of photo diodes are formed; a plurality of interlayer dielectrics formed above the semiconductor substrate; a plurality of metal lines formed on each of the interlayer dielectrics; and a plurality of micro lenses formed above the uppermost one of the interlayer dielectrics, the lights passing through the zoom lenses being incident on the respective micro lenses, wherein the metal lines formed one of the interlayer dielectrics have identical widths.

According to at least some example embodiments, the metal lines having the identical widths may be formed by forming sub-metal lines one the metal lines each having a relatively narrow width. The metal lines having the identical widths may be formed on the uppermost interlayer dielectric. A central axis of each of the micro lenses may be misaligned with a central axis of each of the corresponding photo diodes. The image sensor may further include a plurality of color filters formed between the uppermost interlayer dielectric and the micro lenses.

According to at least some example embodiments the image sensor may further include: a first over-coating layer formed between the uppermost interlayer dielectric and the color filters; and a second over-coating layer formed between the color filters and the micro lenses. The image sensor may further include an over-coating layer formed between the uppermost interlayer dielectric and the micro lenses. The image sensor may be a CMOS (Complementary Metal Oxide Semiconductor) image sensor or a CCD (Charge Coupled Device).

According to another aspect of the present invention, there is provided a method of fabricating an image sensor for detecting lights passing through a zoom lens including: forming a plurality of photo diodes on the semiconductor substrate; forming a plurality of interlayer dielectrics above the semiconductor substrate; forming a plurality of metal lines on each of the interlayer dielectrics; and forming a plurality of micro lenses above the uppermost one of the interlayer dielectrics, the lights passing through the zoom lens being incident on the micro lenses, wherein the forming the plurality of metal lines are performed such that the metal lines formed one of the interlayer dielectrics have identical widths.

According to at least some example embodiments, the forming the plurality of metal lines may include: comparing the widths of the metal lines; and forming sub-metal lines on both side surfaces of the metal lines each having a relatively narrow width so that the widths of the metal lines become identical. The forming the plurality of metal lines may be preformed such that the metal lines formed on the uppermost one of the interlayer dielectrics have identical widths. The forming the plurality of micro lenses may be performed such that a central axis of each of the micro lenses is misaligned with a central axis of each of the corresponding photo diodes. The method may further include forming a plurality of color filters formed between the uppermost interlayer dielectric and the micro lenses. The method may further include: forming a first over-coating layer formed between the uppermost interlayer dielectric and the color filters; and forming a second over-coating layer formed between the color filters and the micro lenses. The method may further include forming an over-coating layer formed between the uppermost interlayer dielectric and the micro lenses. The image sensor may be a CMOS (Complementary Metal Oxide Semiconductor) image sensor or a CCD (Charge Coupled Device).

### BRIEF DESCRIPTION OF THE DRAWINGS

Example embodiments will become more apparent by describing in detail the attached drawings in which:

FIG. 1 is a schematic sectional view of a conventional image sensor;

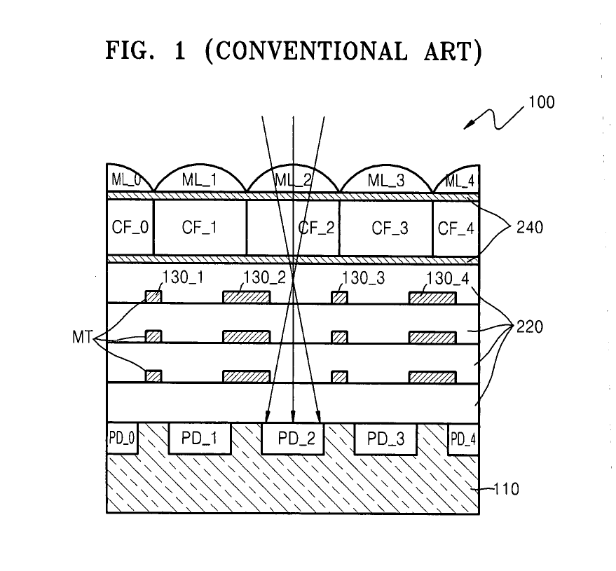

FIG. 2 is a schematic diagram illustrating a light incident on a photo diode in accordance with magnification of a zoom lens according to the conventional art;

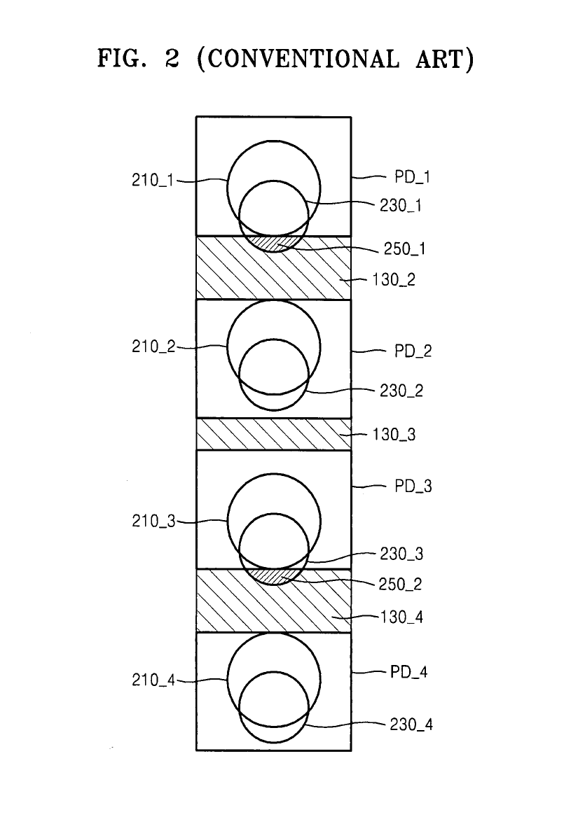

FIG. 3 is a schematic sectional view of an image sensor according to an example embodiment;

FIG. 4 is a top plan view of the image sensor of FIG. 3;

FIG. 5 is a top plan view of the image sensor of FIG. 3, illustrating mounts of lights incident on respective target photo diodes; and

FIG. 6 is a flowchart illustrating a method of fabricating an image sensor according to an example embodiment.

### DETAILED DESCRIPTION OF EXAMPLE EMBODIMENTS

Various example embodiments will now be described more fully with reference to the accompanying drawings in which some example embodiments are shown. In the drawings, the thicknesses of layers and regions are exaggerated for clarity.

Detailed illustrative example embodiments are disclosed herein. However, specific structural and functional details disclosed herein are merely representative for purposes of describing example embodiments. This invention may, however, may be embodied in many alternate forms and should not be construed as limited to only the example embodiments set forth herein.

Accordingly, while example embodiments are capable of various modifications and alternative forms, embodiments thereof are shown by way of example in the drawings and will herein be described in detail. It should be understood, however, that there is no intent to limit example embodiments to the particular forms disclosed, but on the contrary, example embodiments are to cover all modifications, equivalents, and alternatives falling within the scope of the invention. Like numbers refer to like elements throughout the description of the figures.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of example embodiments. As used herein, the term “and/or” includes any and all combinations of one or more of the associated listed items.

It will be understood that when an element or layer is referred to as being “formed on” another element or layer, it can be directly or indirectly formed on the other element or layer. That is, for example, intervening elements or layers may be present. In contrast, when an element or layer is referred to as being “directly formed on” to another element, there are no intervening elements or layers present. Other words used to describe the relationship between elements or layers should be interpreted in a like fashion (e.g., “between” versus “directly between”, “adjacent” versus “directly adjacent”, etc.).

The terminology used herein is for the purpose of describing particular embodiments only and is not intended to be limiting of example embodiments. As used herein, the singular forms “a”, “an” and “the” are intended to include the plural forms as well, unless the context clearly indicates otherwise. It will be further understood that the terms “comprises”, “comprising,”, “includes” and/or “including”, when used herein, specify the presence of stated features, integers, steps, operations, elements, and/or components, but do not preclude the presence or addition of one or more other features, integers, steps, operations, elements, components, and/or groups thereof.

It should also be noted that in some alternative implementations, the functions/acts noted may occur out of the order noted in the FIGS. For example, two FIGS. shown in succession may in fact be executed substantially concurrently or may sometimes be executed in the reverse order, depending upon the functionality/acts involved.

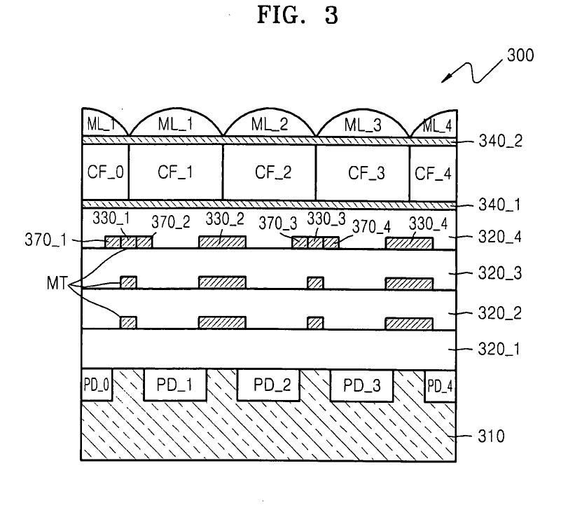

FIG. 3 is a schematic sectional view of an image sensor according to an example embodiment.

Referring to FIG. 3, an example embodiment image sensor 300 may include a semiconductor substrate 310 including a plurality of photo diodes PD_0, PD_1, PD_2, PD_3 and PD_4. A plurality of interlayer dielectrics 320_1, 320_2, 320_3 and 320_4, a plurality of color filters CF_0, CF_1, CF_2, CF_3 and CF_4, and a plurality of micro lenses ML_0, ML_1, ML_2, ML_3 and ML_4 may also be formed on the substrate 310.

The photo diodes PD_0, PD_1, PD_2, PD_3 and PD_4 formed on the semiconductor substrate 310 may output electric signals in response to an intensity of incident light.

The interlayer dielectrics 320_1, 320_2, 320_3 and 320_4 may be formed above the semiconductor substrate 310. Transistors adjacent to the respective photo diodes PD_0, PD_1, PD_2, PD_3 and PD_4 may be formed on the semiconductor substrate 310. The internal dielectrics 320_1, 320_2, 320_3 and 320_4 may insulate gate electrodes of the transistors from metal lines.

The color filters CF_0, CF_1, CF_2, CF_3 and CF_4 may be formed on the uppermost one 320_4 of the interlayer dielectrics 320_1, 320_2, 320_3 and 320_4. Each of the color filters CF_0, CF_1, CF_2, CF_3 and CF_4 may be formed to correspond to the respective photo diodes PD_0, PD_1, PD_2, PD_3 and PD_4 and may include red, green and/or blue colors or yellow, magenta and/or cyan colors.

The micro lenses ML_0, ML_1, ML_2, ML_3 and ML_4 may be formed above the color filters CF_0, CF_1, CF_2, CF_3 and CF_4. To improve photosensitivity, a light harvesting technology for collecting light on a sensitive paper by changing a path of light incident on a region other than a sensitive paper may be applied to image sensors. The micro lenses ML_0, ML_1, ML_2, ML_3 and ML_4 may be used to realize the light harvesting technology. Central axes of the micro lenses ML_0, ML_1, ML_2, ML_3 and ML_4 may be misaligned with those of the corresponding photo diodes PD_0, PD_1, PD_2, PD_3 and PD_4. If the central axes of the micro lenses ML_0, ML_1, ML_2, ML_3 and ML_4 is aligned with those of the corresponding photo diodes PD_0, PD_1, PD_2, PD_3, and PD_4, the light passing through the micro lenses ML_0, ML_1, ML_2, ML_3 and ML_4 may not be directed to the corresponding target photo diodes PD_0, PD_1, PD_2, PD_3 and PD_4, but to peripheral photo diodes.

First and second over-coating layers 340_1 and 340_2 functioning as planar layers may be respectively formed between the uppermost one 320_1 of the interlayer dielectrics 320_1, 320_2, 320_3 and 320_4 and the color filters CF_0, CF_1, CF_2, CF_3 and CF_4 and between the color filters CF_0, CF_1, CF_2, CF_3 and CF_4 and the micro lenses ML_0, ML_1, ML_2, ML_3 and ML_4.

Although not shown in FIG. 3, a lens for transferring externally incident light to the micro lenses ML_0, ML_1, ML_2, ML_3 and ML_4 may be disposed above the micro lenses ML_0, ML_1, ML_2, ML_3 and ML_4. In at least this example embodiment, the lens may be a zoom lens.

A plurality of metal lines MT may be formed on each of the interlayer dielectrics 320_1, 320_2, 320_3 and 320_4. The metal lines MT may be arranged not to interfere with the photo diodes PD_0, PD_, PD_2, PD_3 and PD_4. Sub-metal lines 370_1, 370_2, 370_3 and 370_4 may also be formed in one of the interlayer dielectrics 320_1, 320_2, 320_3 and 320_4 so that the metal lines 330_1, 330_2, 330_3 and 330_4 formed in the interlayer dielectric 320_4 have the same or substantially the same width. For example, the sub-metal lines 370_1 and 370_2 may be formed on each side surface of the metal line 330_1 and the sub-metal lines 370_3 and 370_4 may be formed on each side surface of the metal line 330_3. As described above, the metal lines MT formed in the uppermost interlayer dielectric 320_4 may be corrected to have the same or substantially the same widths. Alternatively, identical or substantially identical effects may be obtained when the metal lines MT formed in other interlayer dielectrics 320_1, 320_2 and 320_3 are formed to have the same or substantially the same width.

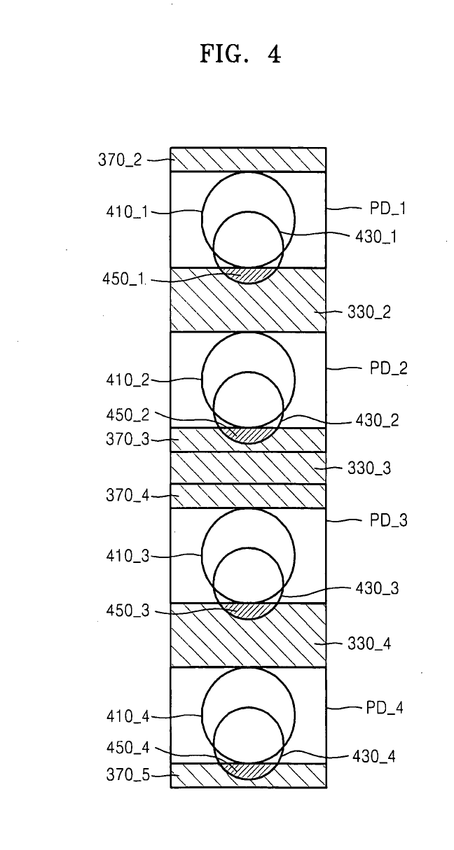

FIG. 4 is a top plan view of the image sensor of FIG. 3. Referring to FIGS. 3 and 4, a case in which a relatively low magnification zoom lens is used will be compared with a case in which a relatively high magnification zoom lens is used. FIG. 4 shows light 410_1, 410_2, 410_3 and 410_4 incident on the respective photo diodes PD_0, PD_1, PD_2, PD_3 and PD_4 through a relatively low magnification zoom lens and light 430_1, 430_2, 430_3 and 430_4 incident on the respective photo diodes PD_0, PD_1, PD_2, PD_3 and PD_4 through a relatively high magnification zoom lens.

Like the conventional art, the light 410_1, 410_2, 410_3 and 410_4 incident through the relatively low magnification lens may be fully directed to the corresponding target photo diodes PD_1, PD_2, PD_3 and PD_4. However, unlike the conventional art, the light 430_1, 430_2, 430_3 and 430_4 incident through the relatively high magnification lens may also be fully directed to the corresponding target photo diodes PD_1, PD_2, PD_3 and PD_4. The sub-metal lines 370_1, 370_2, 370_3 and 370_4 block the same or substantially the same amount of light as an amount of light blocked by the metal lines 330_2 and 330_4. For example, at least a portion of the incident lights 430_2 and 430_4 may be blocked by the sub-metal lines 370_1, 370_2, 370_3 and 370_4. Accordingly, an amount of the light directed to the photo diodes PD_0, PD_1, PD_2, PD_3 and PD_4 may be the same or substantially the same.

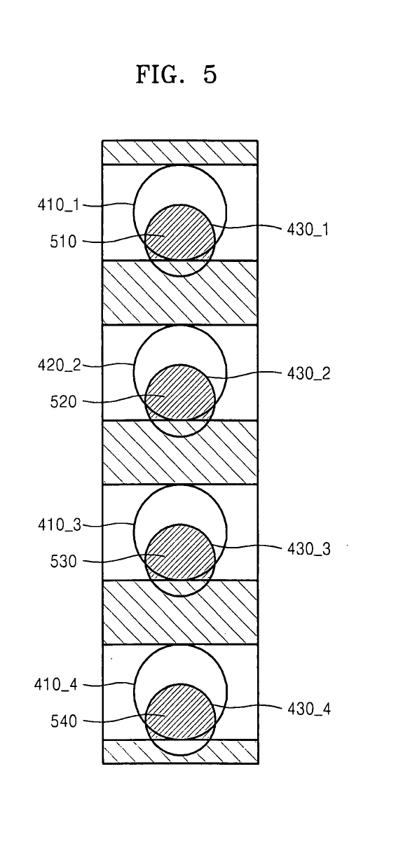

FIG. 5 is a top plan view of the image sensor of FIG. 3, illustrating mounts of lights incident on respective target photo diodes.

Referring to FIGS. 3 through 5, the metal lines MT may have the same or substantially the same width as the interlayer dielectric 320_4 by causing the sub-metal lines 370_1, 370_2, 370_3 and 370_4 and the photo diodes PD_0, PD_1, PD_2, PD_3 and PD_4 to which the light is directed may have the same or substantially the same area. Therefore, the same or substantially the same amount of light may be transmitted to the respective target photo diodes PD_0, PD_1, PD_2, PD_3 and PD_4 regardless of the magnification of the lens. For example, even when the relatively high magnification lens is used, the same or substantially the same amount of light incident through the relatively high magnification zoom lens may be transmitted to the respective target photo diodes PD_0, PD_1, PD_2, PD_3 and PD_4. Further, because the photo diodes PD_0, PD_, PD_2, PD_3 and PD_4 to which the light is directed have the same or substantially the same area, the same or substantially the same amount of light may be transmitted to the respective target photo diodes PD_0, PD_1, PD_2, PD_3 and PD_4 regardless of the magnification of the zoom lens even when the light moves vertically.

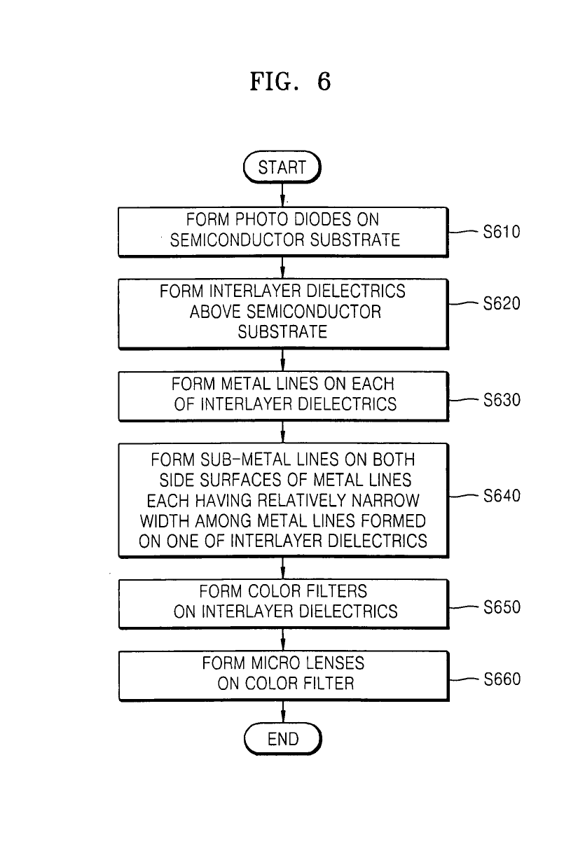

FIG. 6 is a flowchart illustrating a method of fabricating the image sensor according to an example embodiment.

Referring to FIGS. 3 and 6, the photo diodes PD_, PD_1, PD_2, PD_3 and PD_4 may be formed on the semiconductor substrate 310 (S610). The interlayer dielectrics 320_1, 320_2, 320_3 and 320_4 may be formed on the semiconductor substrate 310 (S620). The metal lines MT may be formed on each of the interlayer dielectrics 320_1, 320_2, 320_3 and 320_4 (S630) on side surfaces of each of the metal lines 330_1 and 330_3. Submetal lines 370_1-370_4 may be formed on at least one of the interlayer dielectrics 320_1, 320_2, 320_3, and 320_4 (S640). In at least one example, widths of the metal lines 330_1, 330_2, 330_3 and 330_4 of the interlayer dielectric 320_4 may be compared with each other to determine which of the metal lines 330_1, 330_2, 330_3 and 330_4 have a relatively narrow width. With regard to FIG. 3, for example, the metal lines 330_1 and 330_3 may be identified as having a relatively narrow width. The sub-metal lines 370_1 and 370_2 may be formed on each side surface of the metal line 330_1 and the sub-metal lines 370_3 and 370_4 may be formed on each side surfaces of the metal line 330_3 such that the metal lines 330_1, 330_2, 330_3 and 330_4 have the same or substantially the same width. The first over-coating layer 340_1 may be formed on the uppermost interlayer dielectric 320_4 and the color filters CF_0, CF_1, CF_2, CF_3 and CF_4 may be formed on the first over-coating layer 340_1 (S650). The second over-coating layer 340_2 may be formed above the color filters CF_0, CF_1, CF_2, CF_3 and CF_4, and the micro lenses ML_0, ML_1, ML_2, ML_3 and ML_4 (S660).

Image sensors according to example embodiments may be a complementary metal oxide semiconductor (CMOS) image sensor and/or a charge coupled device (CCD).

According to example embodiments, as sub-metal lines are formed on the existing metal lines, amounts of the light detected by the asymmetric photo diodes may become the same or substantially the same even when a zoom lens is used. Thus, incident angles of the light may vary due to the variation of the magnification, and sensitivity differences between Gr and Gb and/or color tint phenomena may be suppressed and or prevented.

While example embodiments have been particularly shown and described with reference to the drawings, it will be understood by those of ordinary skill in the art that various changes in form and details may be made therein without departing from the spirit and scope of the present invention as defined by the following claims.

What is claimed is:

1. An image sensor for detecting light passing through the zoom lens, the image sensor comprising:
a plurality of interlayer dielectrics formed on a semiconductor substrate, the semiconductor substrate including a plurality of photo diodes;
a plurality of metal lines formed on each of the plurality of interlayer dielectrics; and
a plurality of lenses formed on an uppermost one of the plurality of interlayer dielectrics, the light passing through the zoom lens being incident on the respective lenses; wherein
the plurality of metal lines formed on at least one of the plurality of interlayer dielectrics have the same width.

2. The image sensor of claim 1, wherein at least a portion of the plurality of metal lines include sub-metal lines formed on side surfaces of the plurality of metal lines such that the plurality of metal lines have the same width.

3. The image sensor of claim 1, wherein the plurality of metal lines having the same width are formed on the uppermost interlayer dielectric.

4. The image sensor of claim 1, wherein a central axis of each of the plurality of lenses is not aligned with a central axis of a corresponding one of the plurality of photo diodes.

5. The image sensor of claim 1, further including,
a plurality of color filters formed between the uppermost interlayer dielectric and the plurality of lenses.

6. The image sensor of claim 5, further including,
a first over-coating layer formed between the uppermost interlayer dielectric and the plurality of color filters, and
a second over-coating layer formed between the plurality of color filters and the plurality of lenses.

7. The image sensor of claim 1, further including,
an over-coating layer formed between the uppermost interlayer dielectric and the plurality of lenses.

8. The image sensor of claim 1, wherein the image sensor is a complementary metal oxide semiconductor (CMOS) image sensor or a charge coupled device (CCD).

9. The image sensor of claim 1, wherein the lenses are micro lenses.

10. A method of fabricating an image sensor for detecting light passing through a zoom lens, the method comprising:
forming a plurality of interlayer dielectrics one the semiconductor substrate, the semiconductor substrate including a plurality of photo diodes;
forming a plurality of metal lines on each of the plurality of interlayer dielectrics; and
forming a plurality of lenses above an uppermost one of the plurality of interlayer dielectrics, light passing through the zoom lens being incident on the plurality of lenses; wherein
a plurality of metal lines formed on at least one of the plurality of interlayer dielectrics have the same width.

11. The method of claim 10, wherein the forming the plurality of metal lines includes,
comparing widths of the plurality of metal lines to determine a first portion of the plurality of metal lines having a width less than a width of a second portion of the plurality of metal lines, and
forming sub-metal lines on each side of metal lines in the first portion of the plurality of metal lines such that widths of the plurality of metal lines are the same.

12. The method of claim 10, wherein the plurality of metal lines are formed such that the plurality of metal lines formed on the uppermost interlayer dielectric have the same width.

13. The method of claim 10, wherein the plurality of lenses are formed performed such that a central axis of each of the plurality of lenses is not aligned with a central axis of a corresponding one of the plurality of photo diodes.

14. The method of claim 10, further including,
forming a plurality of color filters between the uppermost interlayer dielectric and the plurality of lenses.

15. The method of claim 14, further including,
forming a first over-coating layer between the uppermost interlayer dielectric and the plurality of color filters, and
forming a second over-coating layer between the plurality of color filters and the plurality of lenses.

16. The method of claim 10, further including,
forming an over-coating layer between the uppermost interlayer dielectric and the plurality of lenses.

17. The method of claim 10, wherein a first portion of the plurality of metal lines on the uppermost dielectric layer have widths less than widths of a second portion of the plurality of metal lines on the uppermost dielectric layer, the forming the plurality of metal lines including,
comparing widths of the plurality of metals lines to determine which of the plurality of metal lines are in the first portion; and
forming sub-metal lines on each side of each metal line in the first portion of the plurality of metal lines such that widths of the plurality of metal lines on the uppermost interlayer dielectric are the same.

18. The method of claim 10, further including,
forming the plurality of photodiodes on the semiconductor substrate.

19. The method of claim 10, wherein the image sensor is a complementary metal oxide semiconductor (CMOS) image sensor or a charge coupled device (CCD).

20. The method of claim 10, wherein the lenses are micro lenses.
